(19) United States
(12) Patent Application Publication
(10) Pub. No.: US 2023/0037617 A1
(43) Pub. Date: Feb. 9, 2023

(54) PACKAGING STRUCTURE, ELECTRONIC DEVICE, AND CHIP PACKAGING METHOD

(71) Applicant: HUAWEI TECHNOLOGIES CO., LTD., Shenzhen (CN)

(72) Inventors: Jiantao ZHENG, Shenzhen (CN); Nan ZHAO, Shenzhen (CN); Shanghsuan CHIANG, Shenzhen (CN); Yu JIANG, Beijing (CN); Jianbiao LU, Shenzhen (CN); Yiwei REN, Shanghai (CN)

(21) Appl. No.: 17/972,689

(22) Filed: Oct. 25, 2022

Related U.S. Application Data
(63) Continuation of application No. PCT/CN2020/087091, filed on Apr. 26, 2020.

(51) Int. Cl. H01L 23/433; H01L 23/367; H01L 23/29; H01L 21/52; H01L 21/56

(52) U.S. Cl. CPC H01L 23/433; H01L 23/367; H01L 23/293; H01L 23/296; H01L 21/52; H01L 21/56; H01L 2224/29109; H01L 2224/29139; H01L 2224/29111; H01L 2224/29147; H01L 2224/29113; H01L 24/29

(57) ABSTRACT

A chip is mounted on a surface of the substrate, and the thermally conductive cover is disposed on a side that is of the chip and that is away from the substrate. There is a filling area on a surface that is of the thermally conductive cover and that faces the substrate, and the filling area is opposite to the chip. There is an accommodation cavity whose opening faces the substrate in the filling area. A thermal interface material layer is filled between the chip and a bottom surface of the accommodation cavity. Between an opening edge of the accommodation cavity and the substrate, there is a first gap connected to the accommodation cavity. The filling material encircles a side surface of the thermal interface material layer, so that the filling material separates the side surface of the thermal interface material layer from air.

### CROSS-REFERENCE TO RELATED APPLICATIONS

This application is a continuation of International Application No. PCT/CN2020/087091, filed on Apr. 26, 2020, the disclosure of which is hereby incorporated by reference in its entirety.

### TECHNICAL FIELD

This disclosure relates to the field of chip packaging technologies, and in particular, to a packaging structure, an electronic device, and a chip packaging method.

### BACKGROUND

Heat is generated during running of a chip (for example, a die in a central processing unit). In particular, according to the Moore's law, a quantity of transistors in the chip increases, and hence heat generation of the chip having the increased quantity of transistors also increases simultaneously. Therefore, heat dissipation needs to be performed on the chip by using a heat spreader, to prevent overheating of the chip from affecting performance. For example, an integrated heat spreader (IHS) made of metal is in contact with one surface of the chip, and exports heat.

When a surface of the heat spreader is in contact with the surface of the chip, because both two contact surfaces are rough to a specific extent, a specific air gap is formed between the two surfaces. Also, because thermal conductivity of air is poor, relatively large interface contact thermal resistance is formed between the heat spreader and the chip. To reduce the foregoing contact thermal resistance, a thermal interface material (TIM) with good thermal conductivity is usually filled between the two contact surfaces, to compensate for the foregoing air gap.

The foregoing thermal interface material is prone to deterioration due to reaction with an element in the air, and consequently, a coefficient of thermal conductivity is reduced. For example, when indium is used as the thermal interface material, the indium is easily oxidized or vulcanized when being exposed to the air.

### SUMMARY

This disclosure provides a packaging structure, an electronic device, and a chip packaging method, to prevent a thermal interface material layer between a chip and a thermally conductive cover from deteriorating due to reaction with an element in air, so that good heat dissipation of the chip is ensured.

According to a first aspect, a packaging structure is provided, and the packaging structure is applied to an electronic device such as a server, a mobile phone, or a tablet computer. The packaging structure includes a substrate, a thermally conductive cover, and at least one chip. Each chip is mounted on a same surface of the substrate, and the thermally conductive cover is disposed on a side that is of the at least one chip and that is away from the substrate. There is at least one filling area on a surface that is of the thermally conductive cover and that faces the substrate. Each filling area corresponds to one or more chips in the at least one chip, and there is an accommodation cavity whose opening faces the substrate in each filling area. A thermal interface material layer is filled between each chip and a bottom surface of a corresponding accommodation cavity. Between at least a partial opening edge of each accommodation cavity and the substrate, there is a first gap connected to the accommodation cavity. During preparation of the packaging structure, an opening of each accommodation cavity is made to face upward, and a pipe pours a filling material into each accommodation cavity through the first gap corresponding to the accommodation cavity; and in each accommodation cavity, the filling material encircles a side surface of each thermal interface material layer. Therefore, the filling material separates the side surface of the thermal interface material layer from air, elements such as oxygen and moisture in the air cannot come into contact with the thermal interface material layer, and the thermal interface material layer is not prone to deterioration caused by reaction with the elements in the air, to ensure good thermal contact between each chip and the thermally conductive cover. This facilitates stable heat dissipation of the chip.

There may be a plurality of manners for the accommodation cavity. In a specific implementable solution, an enclosure rib connected to the thermally conductive cover is disposed along an edge of each filling area, and each enclosure rib and a corresponding filling area form one accommodation cavity.

In a specific implementable solution, one first gap is formed between each enclosure rib and the substrate, so that the pipe may extend above the opening of the accommodation cavity, and the filling material is poured into the accommodation cavity. In addition, this facilitates stress release of the substrate due to a temperature difference.

To take both a filling length of each accommodation cavity and passage of the pipe into consideration, in a specific implementable solution, a width of each first gap is between 30 μm and 2 mm.

In addition to a form in which the first gap is maintained between the enclosure rib and the substrate, in a specific implementable solution, the pipe for pouring the filling material can extend to the opening of the accommodation cavity in the following manner An extension rib is connected between the substrate and an end that is of each enclosure rib and that is away from the thermally conductive cover, the extension rib has a hollow extending from the enclosure rib to the substrate, and the hollow forms the first gap, so that the pipe passes through the first gap.

The enclosure rib and the thermally conductive cover are connected in a plurality of manners. In a specific implementable solution, each enclosure rib and the thermally conductive cover are in a separated structure. In another specific implementable solution, each enclosure rib and the thermally conductive cover are in an integrated structure.

In a specific implementable solution, another form of forming the accommodation cavity is that each filling area is recessed in a direction away from the substrate to form one accommodation cavity.

In a specific implementable solution, the packaging structure further includes a support component, and the support component is disposed between the substrate and the thermally conductive cover and is separately connected to the substrate and the thermally conductive cover. The support component surrounds an accommodation cavity corresponding to the at least one chip, and a second gap corresponding to each first gap is formed between a part of the support component and the substrate. When pouring the filling material into the accommodation cavity, the pipe first passes through the second gap, and then passes through the first gap corresponding to the accommodation cavity into which the filling material is to be poured, to reach the opening of the specified accommodation cavity, and then pours the filling material into the accommodation cavity.

In a specific implementable solution, the support component and the thermally conductive cover are in a separated structure, and in addition, the support component and the thermally conductive cover may alternatively be in an integrated structure.

In a specific implementable solution, in each accommodation cavity, a melting point of the filling material is higher than a melting point of each thermal interface material layer. When the packaging structure is mounted on a circuit board in a high-temperature manner such as reflow soldering, the thermal interface material layer melts, but the filling material that encircles the thermal interface material layer remains solid, so that liquid obtained after the thermal interface material layer melts can be prevented from flowing. After the liquid is cooled, the thermal interface material layer is cooled again, so that good thermal contact between the chip and the thermally conductive cover can be maintained.

In a specific implementable solution, in each accommodation cavity, the filling material covers at least a part of a side surface of each chip, to prevent a gap between the chip and the thermal interface material layer that is caused due to different coefficients of thermal expansion of the chip and the substrate, and this helps ensure stable heat dissipation of the chip.

For example, in a specific implementable solution, in each accommodation cavity, a material of each thermal interface material layer is indium, indium/silver, tin/silver/copper, or indium/tin/bismuth; and

a material of the filling material is one or a combination of more of silica gel, polyolefin resin, epoxy resin, modified epoxy resin, silicone resin, and modified silicone resin.

According to a second aspect, an electronic device is provided, and the electronic device may be a server, a mobile phone, a tablet computer, or the like. The electronic device includes a circuit board and the packaging structure provided in any one of the foregoing technical solutions, and a substrate is mounted on the circuit board and is electrically connected to the circuit board. In the electronic device, because a thermal interface material layer is covered by a filling material, the thermal interface material layer is prevented from deteriorating due to reaction with an element in air, so that heat dissipation stability of a chip is ensured, and performance of the electronic device is improved.

According to a third aspect, a chip packaging method is provided, and includes at least the following steps:

mounting at least one chip on a surface of a substrate;

mounting a thermally conductive cover on a side that is of the at least one chip and that is away from the substrate, where there is at least one filling area on a surface that is of the thermally conductive cover and that faces the substrate, each filling area corresponds to one or more chips in the at least one chip, there is an accommodation cavity whose opening faces the substrate in each filling area, a thermal interface material layer is filled between each chip and a bottom surface of a corresponding accommodation cavity, and between at least a partial opening edge of each accommodation cavity and the substrate, there is a first gap connected to the accommodation cavity; and

pouring a filling material into each accommodation cavity through the first gap corresponding to the accommodation cavity, and curing the filling material, where in each accommodation cavity, the filling material encircles at least a side surface of the thermal interface material layer.

In a specific implementable solution, before the mounting a thermally conductive cover on a side that is of the at least one chip and that is away from the substrate, the method further includes:

forming the accommodation cavity in each filling area of the thermally conductive cover.

The accommodation cavity may be formed in a plurality of manners. In a specific implementable solution, the forming the accommodation cavity in each filling area of the thermally conductive cover specifically includes:

forming an enclosure rib along an edge of each filling area of the thermally conductive cover, where each enclosure rib and a corresponding filling area form one accommodation cavity.

In another specific implementable solution, the forming the accommodation cavity in each filling area of the thermally conductive cover specifically includes:

forming, in each filling area of the thermally conductive cover, a groove that is recessed toward an inner side of the thermally conductive cover, where each groove forms one accommodation cavity.

In a specific implementable solution, the mounting a thermally conductive cover on a side that is of the at least one chip and that is away from the substrate specifically includes:

fastening at least one extension rib to the substrate, where each extension rib surrounds one or more chips, an enclosure rib is disposed along an end that is of each extension rib and that is away from the substrate, each extension rib has a hollow, and the hollow extends from the substrate to a corresponding enclosure rib, to form the first gap; and

placing the thermally conductive cover on the side that is of the at least one chip and that is away from the substrate, and enabling an end that is of each enclosure rib and that is away from a corresponding extension rib to be connected to the thermally conductive cover, where each enclosure rib extends along an edge of a corresponding filling area, and each enclosure rib and the corresponding filling area form one accommodation cavity.

In a specific implementable solution, the mounting a thermally conductive cover on a side that is of the at least one chip and that is away from the substrate specifically includes:

fastening a support component to the substrate, where the support component surrounds the at least one chip, and a second gap is formed between a part of the support component and the substrate; and

placing the thermally conductive cover on the side that is of the at least one chip and that is away from the substrate, and enabling an end that is of the support component and that is away from the substrate to be connected to the thermally conductive cover, where the second gap corresponds to each first gap.

In a specific implementable solution, before the fastening a support component to the substrate, the method further includes:

forming, on the support component, a dent used to cooperate with the substrate to form the second gap.

In a specific implementable solution, a support component is disposed on a surface that is of the thermally conductive cover and that has a filling area, where the support component surrounds an accommodation cavity corresponding to at least one filling area, and there is a dent on an end that is of the support component and that is away from the thermally conductive cover; and

the mounting a thermally conductive cover on a side that is of the at least one chip and that is away from the substrate specifically includes:

placing the thermally conductive cover on the side that is of the at least one chip and that is away from the substrate, and enabling an end that is of the support component and that is away from the thermally conductive cover to be connected to the substrate, where the dent cooperates with the substrate to form a second gap corresponding to each first gap.

In a specific implementable solution, before the placing the thermally conductive cover on the side that is of the at least one chip and that is away from the substrate, the method further includes:

forming the dent at the end that is of the support component and that is away from the thermally conductive cover.

In a specific implementable solution, before the mounting a thermally conductive cover on a side that is of the at least one chip and that is away from the substrate, the method further includes:

forming the thermal interface material layer on a surface that is of each chip and that is away from the substrate.

Because the thermal interface material layer is covered by the filling material, the thermal interface material layer is prevented from deteriorating due to reaction with an element in air, so that heat dissipation stability of the chip is ensured, and performance of an electronic device is improved.

### BRIEF DESCRIPTION OF DRAWINGS

FIG. 1a is a schematic diagram of a packaging structure;

FIG. 1b is a schematic diagram of the packaging structure in FIG. 1a after the packaging structure is cooled and deformed;

FIG. 2 is a schematic diagram of an application scenario of a packaging structure according to an embodiment of this disclosure;

FIG. 3a is a schematic diagram of a packaging structure according to an embodiment of this disclosure;

FIG. 3b is a bottom view of a heat spreader in FIG. 3a;

FIG. 3c is a side view of a heat spreader in FIG. 3a;

FIG. 3d shows distribution of an adhesive on a heat spreader in FIG. 3a;

FIG. 4a is a schematic diagram of another packaging structure according to an embodiment of this disclosure;

FIG. 4b is a bottom view of a heat spreader in FIG. 4a;

FIG. 5a is a schematic diagram of another packaging structure according to an embodiment of this disclosure;

FIG. 5b is a bottom view of a heat spreader in the packaging structure shown in FIG. 5a;

FIG. 6 is a schematic diagram of cooperation between a packaging structure and a circuit board in an electronic device according to an embodiment of this disclosure;

FIG. 7a is a schematic diagram of another packaging structure according to an embodiment of this disclosure;

FIG. 7b is a bottom view of a heat spreader in FIG. 7a;

FIG. 7c is a schematic diagram of another packaging structure according to an embodiment of this disclosure;

FIG. 7d is a bottom view of a heat spreader in FIG. 7c;

FIG. 8a is a schematic diagram of a structure obtained after step S110 is performed in a chip packaging method according to an embodiment of this disclosure;

FIG. 8b is a schematic diagram of a structure obtained after step S120 is performed in a chip packaging method according to an embodiment of this disclosure;

FIG. 8c is a schematic diagram of a structure obtained after step S210 is performed in a chip packaging method according to an embodiment of this disclosure;

FIG. 8d is a schematic diagram of a structure obtained after step S220 is performed in a chip packaging method according to an embodiment of this disclosure;

FIG. 8e is a schematic diagram of a structure obtained after step S300 is performed in a chip packaging method according to an embodiment of this disclosure;

FIG. 8f is a schematic diagram of a structure obtained after step S410 is performed in a chip packaging method according to an embodiment of this disclosure;

FIG. 8g is a schematic diagram of a structure obtained after step S500 is performed in a chip packaging method according to an embodiment of this disclosure;

FIG. 9a is a schematic diagram of a structure obtained after step S221 is performed in a chip packaging method according to an embodiment of this disclosure;

FIG. 9b is a schematic diagram of a structure obtained after step S222 is performed in a chip packaging method according to an embodiment of this disclosure;

FIG. 10a is a schematic diagram of a structure obtained after step S230 is performed in a chip packaging method according to an embodiment of this disclosure; and

FIG. 10b is a schematic diagram of a structure obtained after step S240 is performed in a chip packaging method according to an embodiment of this disclosure.

### DESCRIPTION OF EMBODIMENTS

To make objectives, technical solutions, and advantages of this disclosure clearer, the following further describes this disclosure in detail with reference to the accompanying drawings.

FIG. 1a is a schematic diagram of a packaging structure. FIG. 1b is a schematic diagram of the packaging structure after the packaging structure is cooled and deformed. As shown in FIG. la, a chip 05 is electrically connected to a pad on a substrate 02 by using a solder ball 06, a heat spreader 01 includes a thermally conductive cover 011 and an annular support component 012, the thermally conductive cover 011 covers a side that is of the chip 05 and that is away from the substrate 02, the annular support component 012 is disposed on a side that is of the thermally conductive cover 011 and that faces the substrate 02, the annular support component 012 is disposed around the chip 05, the annular support component 012 is connected to the thermally conductive cover 011 and is connected to the substrate 02 by using an adhesive 03, and a thermal interface material layer 04 is filled between the chip 05 and the thermally conductive cover 011. The thermal interface material layer 04 is usually made of indium, and is exposed to air, and is prone to deterioration due to reaction with oxygen and moisture in the air, for example, is oxidized or vulcanized. This affects thermal conductivity of the thermal interface material layer 04.

In addition, because the substrate 02 further needs to be mounted on a circuit board in a high-temperature manner such as reflow soldering, the indium melts when being heated, and flows out between the chip 05 and the thermally conductive cover 011. This affects heat dissipation of the chip 05.

In addition, a coefficient of thermal expansion of the substrate 02 is greater than a coefficient of thermal expansion of the chip 05. Therefore, after the chip 05 is mounted on the substrate 02 by using the solder ball 06 at high temperature (generally approximately 150° C.), as shown in FIG. 1b, when the packaging structure is cooled to room temperature (generally approximately 25° C.), the substrate 02 contracts by a relatively large amplitude, and an edge of the chip 05 is pulled by the substrate 02 toward a middle part, and consequently, the middle part of the chip 05 is raised, the edge sinks, and a gap c1 is formed between the edge and the thermal interface material layer 04. Therefore, good contact between the edge of the chip 05 and the thermal interface material layer 04 cannot be maintained, and heat dissipation of the chip 05 is poor.

To resolve the foregoing technical problem, an embodiment of this disclosure provides a packaging structure.

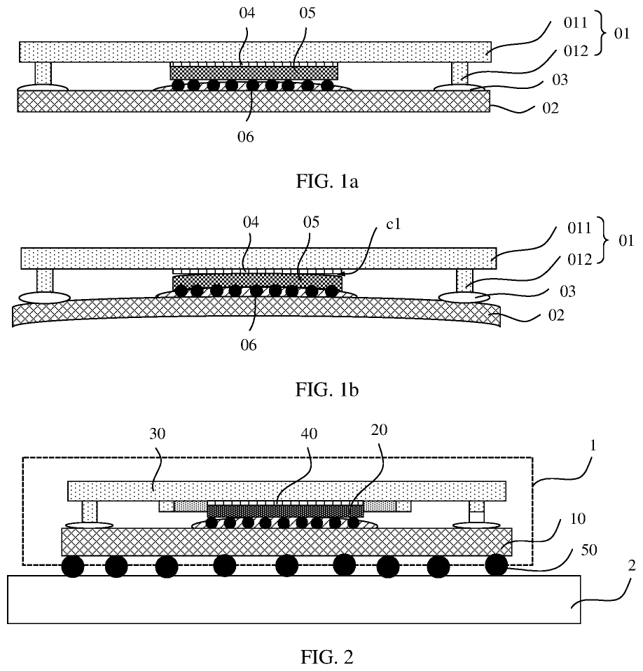

For ease of understanding of the packaging structure provided in this embodiment of this disclosure, an application scenario of the packaging structure provided in this embodiment of this disclosure is described first. The packaging structure is applied to an electronic device such as a server, a computer, a tablet computer, or a mobile phone. FIG. 2 is a schematic diagram of an application scenario of a packaging structure according to an embodiment of this disclosure. As shown in FIG. 2, the packaging structure includes a substrate 10, a chip 20, a heat spreader 30, and a thermal interface material layer 40. The chip 20 may be a die, and is mounted on a surface of the substrate 10 in a manner such as a solder ball. The heat spreader 30 covers a surface that is of the chip 20 and that is away from the substrate 10. The thermal interface material layer 40 is filled between the heat spreader 30 and the chip 20. Heat of the chip 20 is conducted to the heat spreader 30 by using the thermal interface material layer 40, and is dissipated by the heat spreader 30. A surface that is of the substrate 10 and that is away from the chip 20 is mounted on a circuit board 2 in a manner such as a solder ball (whose reference numeral is 50). The circuit board 2 may be a printed circuit board (PCB), or may be another type of circuit board.

The following describes, in detail with reference to the accompanying drawings, the packaging structure provided in this embodiment of this disclosure.

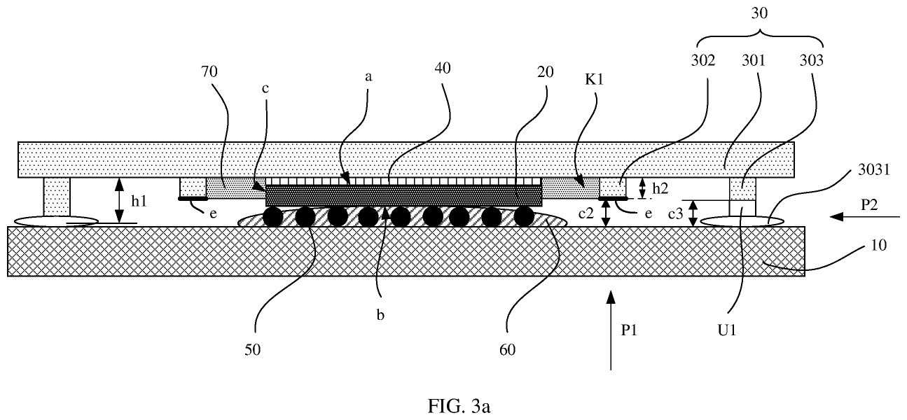

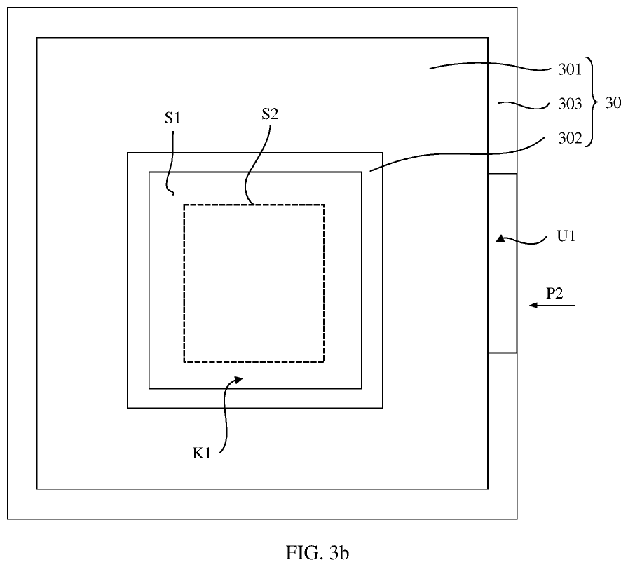

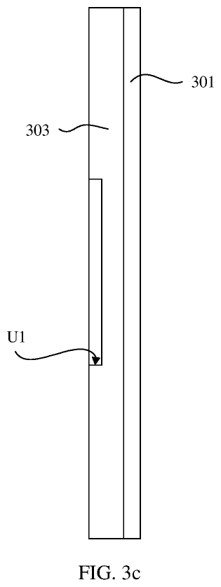

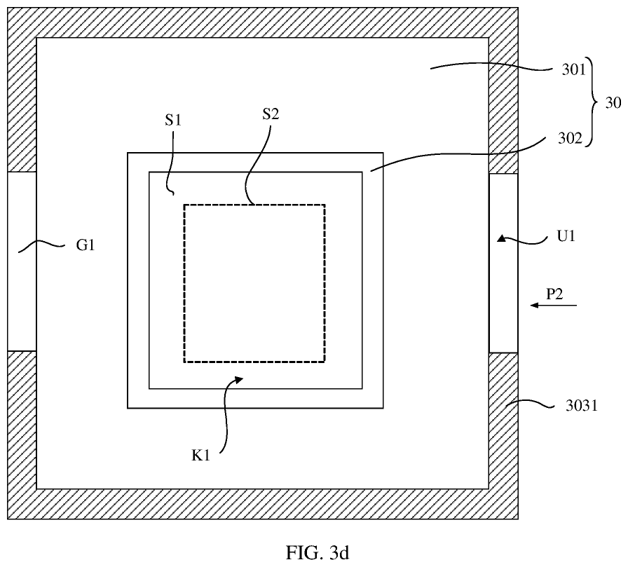

FIG. 3a is a schematic diagram of a packaging structure according to an embodiment of this disclosure. First, as shown in FIG. 3a, the packaging structure includes a substrate 10, a chip 20, a heat spreader 30, and a thermal interface material layer 40. The heat spreader 30 includes a thermally conductive cover 301, a support component 303, and an enclosure rib 302. Materials of the thermally conductive cover 301, the support component 303, and the enclosure rib 302 may all be copper, aluminum, or copper-aluminum alloy. However, the thermally conductive cover 301 is not limited to the foregoing materials, provided that the thermally conductive cover 301 is a plate-shaped structure made of a material with a relatively large coefficient of thermal conductivity. The chip 20 has a top surface a, a bottom surface b, and a side surface c, the top surface a and the bottom surface b are disposed opposite to each other, and the side surface c connects the top surface a and the bottom surface b. In the foregoing surfaces of the chip 20, the “top surface” means a surface that is of the chip 20 and that is away from the substrate during packaging, the “bottom surface” means a surface that is of the chip 20 and that faces the substrate during packaging, and the “side surface” means a surface connecting the “top surface” and the “bottom surface”. The “substrate” means a plate-shaped structure that can bear the chip 20, and has a wire that can be connected from a surface facing the chip 20 to a surface away from the chip 20, and may be a circuit board, or may be another board.

With continued reference to FIG. 3a, the bottom surface b of the chip 20 is mounted, in a form of an flip chip ball grid array (FCBGA), on a surface that is of the substrate 10 and that faces the thermally conductive cover 301. Specifically, the chip 20 is electrically connected to a pad on a surface of the substrate 10 by using a plurality of solder balls 50 distributed in an array. An underfill 60 is filled between the bottom surface b of the chip 20 and the substrate 10, and the underfill 60 encircles the solder balls 50. The underfill 60 may be a material commonly used in the art such as epoxy resin, and the underfill 60 can effectively improve mechanical strength of the solder balls 50, so that the solder balls 50 are separately connected to the chip 20 and the substrate 10 more firmly. However, this is merely an example, and the chip 20 may alternatively be mounted on the substrate 10 in another manner, for example, in a form of an flip chip land grid array (FCLGA).

FIG. 3b is a bottom view (a view observed in a direction P1 in FIG. 3a) of the heat spreader 30 in FIG. 3a. As shown in FIG. 3b, there is a filling area S1 on one surface of the thermally conductive cover 301. For example, the filling area S1 is located in a middle part of a surface that is of the thermally conductive cover 301 and that faces the substrate 10. There is also a chip heat-conducting area S2 in the filling area S1, and an area of the filling area S1 is greater than an area of the chip heat-conducting area S2. The enclosure rib 302 extends along an edge of the filling area S1 and is connected to the thermally conductive cover 301, and any segment of the enclosure rib 302 keeps continuous, so that the enclosure rib 302 and the filling area S1 form one accommodation cavity K1. The “accommodation cavity” is a groove-shaped structure that can accommodate a liquid material and restrict flowing of the liquid material, and has a bottom surface and a side surface disposed along an edge of the bottom surface, and a shape of the bottom surface is not limited to a square in FIG. 3a, and may alternatively be a closed shape such as a rectangle, a circle, or an oval. The support component 303 and the enclosure rib 302 are disposed on a same surface of the thermally conductive cover 301, and are connected to the thermally conductive cover 301. In addition, the support component 303 is located on a periphery of the enclosure rib 302, and is disposed around the enclosure rib 302.

With reference to FIG. 3a again, the thermally conductive cover 301 is located on a side that is of the chip 20 and that is away from the substrate 10, an opening of the accommodation cavity K1 faces the substrate 10, a part of the chip 20 is also accommodated in the accommodation cavity K1, a surface that is of the support component 303 and that is away from the thermally conductive cover 301 is bonded to the substrate 10 by using an adhesive 3031 or the like, and one or more of a silicone elastomer adhesive, an epoxy adhesive, a modified epoxy resin adhesive, or a modified silicone adhesive may be selected as the adhesive 3031. The top surface a of the chip 20 is disposed opposite to the chip heat-conducting area S2 of the thermally conductive cover 301. The “opposite disposing” herein means that an orthographic projection of the top surface a on the surface that is of the thermally conductive cover 301 and that faces the substrate 10 overlaps the chip heat-conducting area S2. The thermal interface material layer 40 is filled between the chip heat-conducting area S2 and the top surface a of the chip 20, and the thermal interface material layer 40 has a first surface and a second surface that are disposed opposite to each other. The first surface is in contact with the thermally conductive cover 301, and the second surface is in contact with the chip 20.

For example, a material of the thermal interface material layer 40 is indium, and a thickness of the thermal interface material layer 40 is between 25 μm and 200 μm, for example, may be 25 μm, 50 μm, 60 μm, 80 μm, 100 μm, 120 μm, 150 μm, 180 μm, or 200 μm. The foregoing descriptions of the thermal interface material layer 40 are merely an example. For example, in addition to the indium, the material of the thermal interface material layer 40 may alternatively be a metal material with a relatively large coefficient of thermal conductivity, such as indium/silver, tin/silver/copper, or indium/tin/bismuth, or may be a non-metal material with a relatively large coefficient of thermal conductivity. In addition, in the accommodation cavity K1, a part of the side surface c of the chip 20 is disposed opposite to the enclosure rib 302, that is, a part of the chip 20 extends into the accommodation cavity K1, and a filling material 70 is filled between the side surface c of the chip 20 and the enclosure rib 302. The “filling material” herein is a viscous material that has specific hydrophobicity, and the “viscous material” is a material that can combine two parts together by using viscous force of the viscous material. The filling material 70 covers a part of the side surface c of the chip 20, and the filling material 70 may be one or a combination of more of insulating materials such as silica gel, polyolefin resin, epoxy resin, modified epoxy resin, silicone resin, and modified silicone resin. Because the filling material 70 is an insulating material, a pin of the chip 20 can be prevented from being short circuited. The filling material 70 covers an entire side surface of the thermal interface material layer 40. The “side surface” of the thermal interface material layer 40 is a surface that connects the first surface (the surface in contact with the thermally conductive cover 301) and the second surface (the surface in contact with the chip 20) of the thermal interface material layer 40, to prevent the thermal interface material layer 40 from deteriorating due to damage from an element in air. For example, when the thermal interface material layer 40 is indium, moisture, oxygen, and the like in the air are blocked by the filling material 70, and cannot come into contact with the thermal interface material layer 40, and the thermal interface material layer 40 is not oxidized or vulcanized. As described above, one of functions of the accommodation cavity K1 is to limit the filling material 70 when the filling material 70 is poured into the accommodation cavity K1, and to prevent flowing of the filling material 70 before the filling material 70 is cured.

FIG. 3c is a side view of the heat spreader 30 in FIG. 3a, that is, a view in a direction P2 in FIG. 3b. As shown in FIG. 3c, a dent U1 is disposed on the support component 303, and the dent U1 is formed after the surface that is of the support component 303 and that is away from the thermally conductive cover 301 is recessed toward the thermally conductive cover 301. A function of the dent U1 is as follows: When the packaging structure is formed, the dent U1 cooperates with the substrate 10 to form a second gap c3 (refer to FIG. 3a), so that the opening of the accommodation cavity K1 faces upward, and the filling material 70 is poured into the accommodation cavity K1 through the second gap c3 in a form of a pipe or the like (refer to FIG. 3a), and there is no need to dispose a hole on the thermally conductive cover 301 for pouring the filling material 70. In addition, the dent U1 further has a function of adjusting air pressure of air in limited space enclosed by the heat spreader 30 and the substrate 10 and air pressure of external air, to prevent the following case: due to a temperature change, the air in the limited space expands when being heated and contracts when being cooled, and consequently, the air pressure changes, and performance of the chip 20 is affected. However, it should be understood that a form of the dent U1 is not limited to a form of collapse of the support component 303; or may be that the support component includes a plurality of support legs disposed at intervals, and a gap between the support legs is used as the dent on the support component, provided that the pipe for pouring the filling material 70 can pour the filling material 70 into the accommodation cavity K1 through the support component 303.

FIG. 3d shows distribution of the adhesive 3031 on the heat spreader 30 in FIG. 3a. As shown in FIG. 3d, the adhesive 3031 does not cover the entire surface that is of the support component 303 and that is away from the thermally conductive cover 301, but a notch G1 is reserved, so that the air in the limited space enclosed by the heat spreader 30 and the substrate 10 can be better connected to the external air, to prevent the following case: due to a temperature change, the air in the limited space expands when being heated and contracts when being cooled, and consequently, the air pressure changes, and performance of the chip 20 is affected. However, because the dent U1 is reserved, an effect of adjusting the air pressure can also be achieved, the notch of the adhesive 3031 may be not disposed.

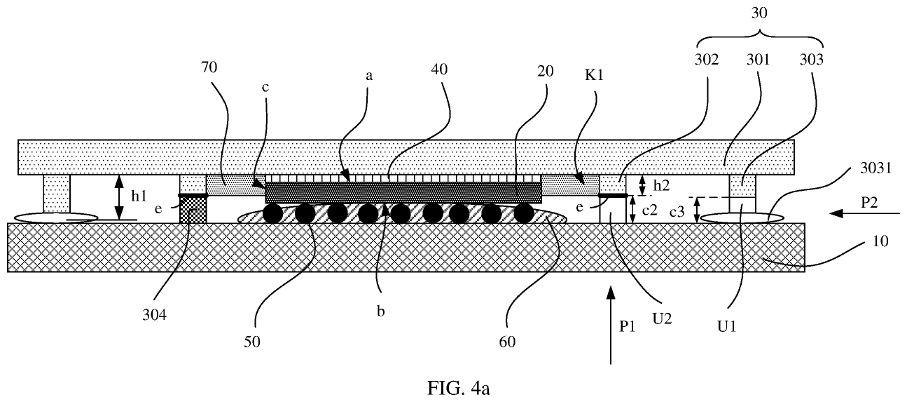

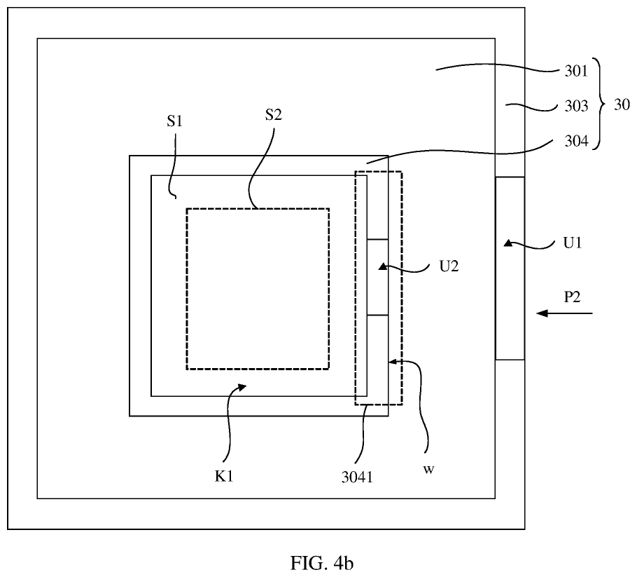

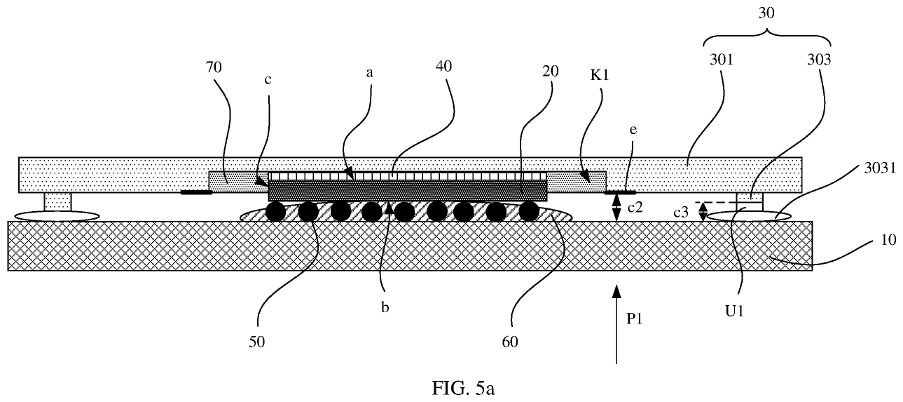

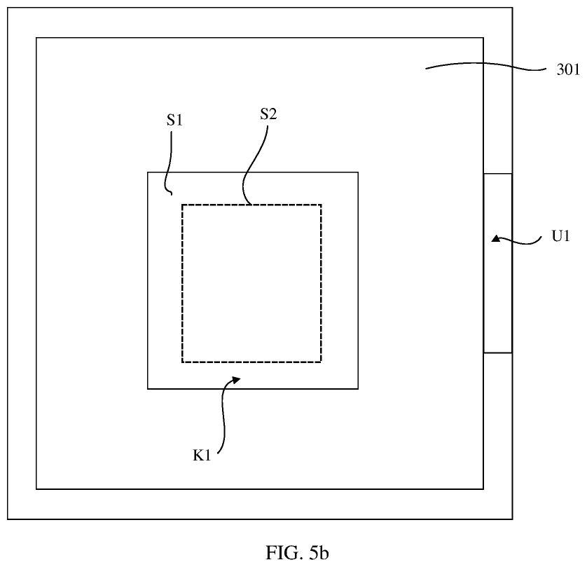

With reference to FIG. 3a again, in a thickness direction (parallel to the direction P1) of the thermally conductive cover 301, a height hl of the support component 303 is greater than a height h2 of the enclosure rib 302, so that a first gap c2 connected to the accommodation cavity K1 is formed between an opening edge of the accommodation cavity K1 and the substrate 10. In this embodiment of this disclosure, the “opening edge” is an annular area with a specific width that is formed after an annular side of a side surface of the accommodation cavity away from a bottom surface extends to a periphery of the accommodation cavity. For details, refer to a surface e that is of the enclosure rib 302 and that faces the substrate 10 (refer to a bold black line location indicated by e in the figure) in FIG. 3a. In the following descriptions, other types of opening edges are listed, such as a surface e shown in FIG. 4a and a surface e shown in FIG. 5a. When the filling material 70 is poured into the accommodation cavity K1 by using the pipe, the pipe may pass through the first gap c2 and extend into the opening or an inner side of the accommodation cavity K1. To take both a requirement of pouring the filling material 70 into the accommodation cavity K1 and a requirement for a depth of the accommodation cavity K1 (to ensure a filling amount of the filling material 70) into consideration, a width (a dimension in the direction P1) of the first gap c2 ranges from 30 μm to 2 mm, for example, may be 30 μm, 70 μm, 100 μm, 200 μm, 300 μm, 400 μm, 600 μm, 750 μm, 1 mm, 1.5 mm, 1.8 mm, or 2 mm. In addition, due to existence of the first gap c2, the substrate 10 is not fastened by the enclosure rib 302, and a coefficient of thermal expansion of the substrate 10 is different from that of the thermally conductive cover 301. When temperature changes, an expansion/contraction degree of the thermally conductive cover 301 and an expansion/contraction degree of the substrate 10 are different, and stress generated by the substrate 10 due to a temperature difference may be released through expansion/contraction. If the substrate 10 is fastened by the enclosure rib 302, the stress cannot be fully released, and consequently, service life of the substrate 10 is shortened. In addition, the first gap c2 is maintained between the enclosure rib 302 and the substrate 10, and this further helps prevent the following case: the enclosure rib 302 is in contact with the substrate 10, and consequently, the enclosure rib encloses the chip 20 in sealed space, and because air pressure of air in the sealed space changes with temperature, performance of the chip 20 is affected.

FIG. 4a is a schematic diagram of another packaging structure according to an embodiment of this disclosure. FIG. 4b is a bottom view of a heat spreader in FIG. 4a. A difference between a thermally conductive cover 301 shown in FIG. 4a and FIG. 4b and the thermally conductive cover 301 shown in FIG. 3b lies in that an extension rib 304 is disposed along the opening edge (that is, an end face e that is of the enclosure rib 302 and that is away from the thermally conductive cover 301; refer to a bold black line location indicated by e in the figure) of the accommodation cavity K1, and one end that is of the extension rib 304 and that is away from the enclosure rib 302 is connected to the substrate 10. There is a hollow U2 on a sidewall 3041 that is of the extension rib 304 and that is close to the dent U1, and the hollow U2 extends from a partial end face e of the enclosure rib 302 to the substrate 10. The hollow U2 forms the first gap c2 between the opening edge of the accommodation cavity K1 and the substrate 10. The hollow U2 corresponds to the dent U1, and the “correspondence” herein means that an orthographic projection of the dent U1 on a reference surface (denoted as w) and an orthographic projection of the hollow U2 on the reference surface w partially or entirely overlap. A plane on which a surface, facing the support component 303, of the sidewall 3041 that is of the extension rib 304 and on which the hollow U2 is disposed is used as the reference surface w. Therefore, the second gap c3 may correspond to the first gap c2. When the filling material 70 is poured into the accommodation cavity K1 by using the pipe, the pipe may pass through the first gap c2 and extend into the opening or the inner side of the accommodation cavity K1. In addition, this also helps balance air pressure in limited space enclosed by the extension rib 304 and the enclosure rib 302 with the external air pressure, to prevent the air pressure in the limited space from changing with temperature.

With reference to FIG. 3a in this embodiment of this disclosure again, because the filling material 70 is a viscous material such as silica gel or polyolefin resin, the filling material 70 may separately firmly fasten the side surface c of the chip 20 to the enclosure rib 302 and the thermally conductive cover 301, to alleviate or even avoid a problem that a gap (refer to the gap c1 in FIG. 1b) between the thermal interface material layer 40 and the chip 20 is caused by contraction of the substrate 10 on the edge of the chip 20. In this way, good contact between the chip 20 and the thermal interface material layer 40 is ensured, and good heat dissipation of the chip 20 is achieved. However, it should be understood that a material of the filling material 70 is not limited to the foregoing material, provided that enough viscosity of the filling material 70 is ensured. In addition, the filling material 70 needs to be in contact with at least a part of the side surface c of the chip 20.

In addition, during selection of a material combination of the filling material 70 and the thermal interface material layer 40, a melting point of the filling material 70 may be higher than a melting point of the thermal interface material layer 40, and the melting point of the filling material 70 is higher than temperature near a soldering point for reflow soldering. For example, the filling material 70 is silica gel, and the thermal interface material layer 40 is indium. When the substrate 10 is mounted on the substrate 10 in an FCB GA manner, a reflow soldering process needs to be used. Temperature of the indium is heated to 200° C. or higher. The indium melts due to a relatively low melting point (generally approximately 156.61° C.), but a melting point of the silica gel is high and does not melt. Therefore, although the indium melts, a flowing range of the indium is still limited by the silica gel, so that good thermal contact between the chip 20 and the thermally conductive cover 301 is maintained. A similar effect can also be achieved when another material combination in which the melting point of the filling material 70 may be higher than the melting point of the thermal interface material layer 40 is used.

It should be noted that the filling material 70 may fill the entire accommodation cavity K1, or may fill some space in the accommodation cavity K1. Even if the filling material 70 is not in contact with the side surface c of the chip 20, a function of preventing air from being in contact with the thermal interface material layer 40 can be achieved provided that the side surface of the thermal interface material layer 40 can be covered.

It should be noted that, the thermally conductive cover 301, the support component 303, and the enclosure rib 302 use a same material and are formed integrally. However, this is merely an example, copper, aluminum, copper-aluminum alloy, or another material with a large coefficient of thermal conductivity is used, provided that relatively good thermal conductivity of the thermally conductive cover 301 is ensured. The support component 303 and the enclosure rib 302 may use a material different from that of the thermally conductive cover 301. In addition, regardless of whether the thermally conductive cover 301, the support component 303, and the enclosure rib 302 use a same material, the support component 303 and the enclosure rib 302 may each form a separated structure with the thermally conductive cover 301; in other words, the support component 303 and the thermally conductive cover 301 are not formed integrally, and the enclosure rib 302 and the thermally conductive cover 301 are not formed integrally. For example, the support component 303 and the enclosure rib 302 each use an independent annular structure. When the thermally conductive cover 301 and the support component 303 use a same material, the thermally conductive cover 301 and the support component 303 may be formed integrally. Similarly, when the thermally conductive cover 301 and the enclosure rib 302 use a same material, the thermally conductive cover 301 and the enclosure rib 302 may be formed integrally.

In addition, it should be understood that a manner of forming the accommodation cavity K1 on the thermally conductive cover is not limited to a manner in which the enclosure rib 302 is used to form the accommodation cavity K1 in FIG. 3b, or another manner may be used, provided that the opening of the accommodation cavity faces the substrate 10. FIG. 5a is a schematic diagram of another packaging structure according to an embodiment of this disclosure. FIG. 5b is a bottom view of a heat spreader 30 in the packaging structure shown in FIG. 5a. With reference to FIG. 5a and FIG. 5b, compared with the embodiment corresponding to the packaging structure shown in FIG. 3a, a difference in the packaging structure shown in FIG. 5a lies in that the filling area S1 of the thermally conductive cover 301 is recessed in a direction away from the substrate 10 to form a groove whose opening faces the substrate 10, and the groove is used as the accommodation cavity K1. The groove may be specifically formed in a plurality of manners, such as etching, stamping, or cutting. For a cooperation manner of the chip 20, the thermal interface material layer 40, the filling material 70, and the accommodation cavity K1, refer to the embodiment corresponding to the packaging structure shown in FIG. 3a. It should be noted that the first gap c2 through which the pipe for pouring the filling material 70 into the accommodation cavity K1 can pass is formed between an opening edge e of the accommodation cavity K1 and the substrate 10. For the opening edge e of the accommodation cavity, refer to an annular area, on a periphery of the opening of the accommodation cavity K1 in FIG. 5a, of the surface that is of the thermally conductive cover 301 and that faces the substrate 10. For a specific location, refer to a bold black line location indicated by e in the figure. In addition, it should be noted that, in FIG. 5a and FIG. 5b, the filling area S1 (that is, a bottom surface of the accommodation cavity K1) is still considered as the surface that is of the thermally conductive cover 301 and that faces the substrate 10.

In the packaging structure in the foregoing embodiments, only one accommodation cavity is formed on each thermally conductive cover, to package one chip. However, this formation is not limited. Alternatively, there are a plurality of filling areas on the thermally conductive cover, and one accommodation cavity is correspondingly formed in each filling area, to separately package a plurality of chips on the substrate.

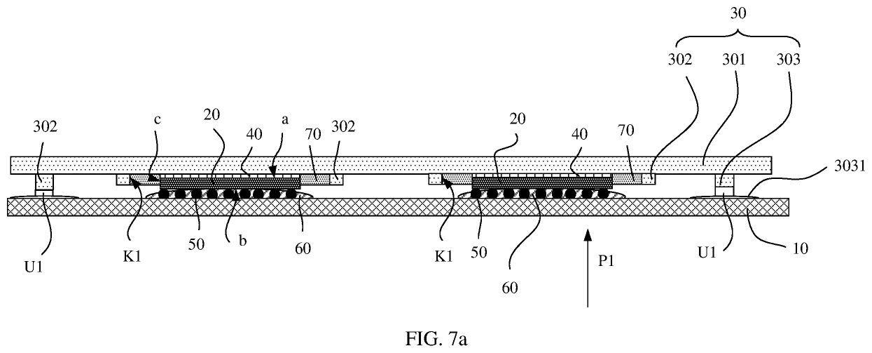

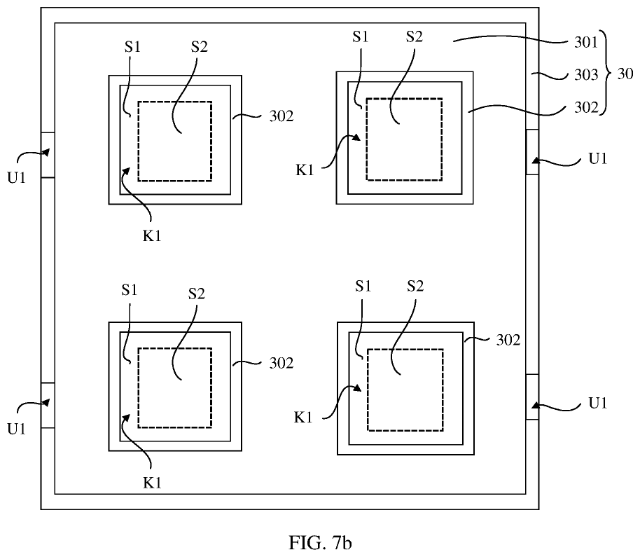

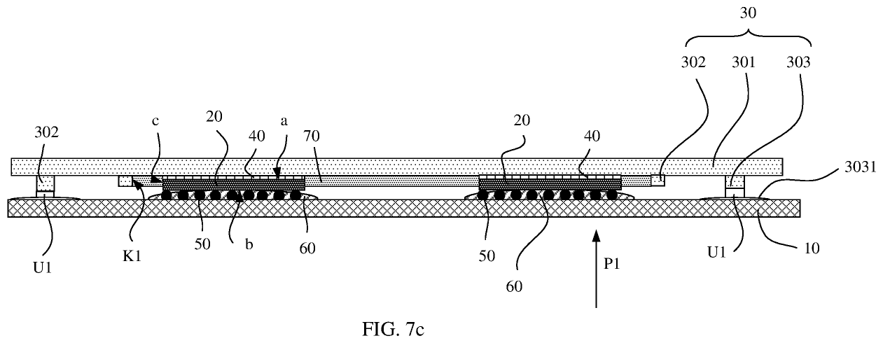

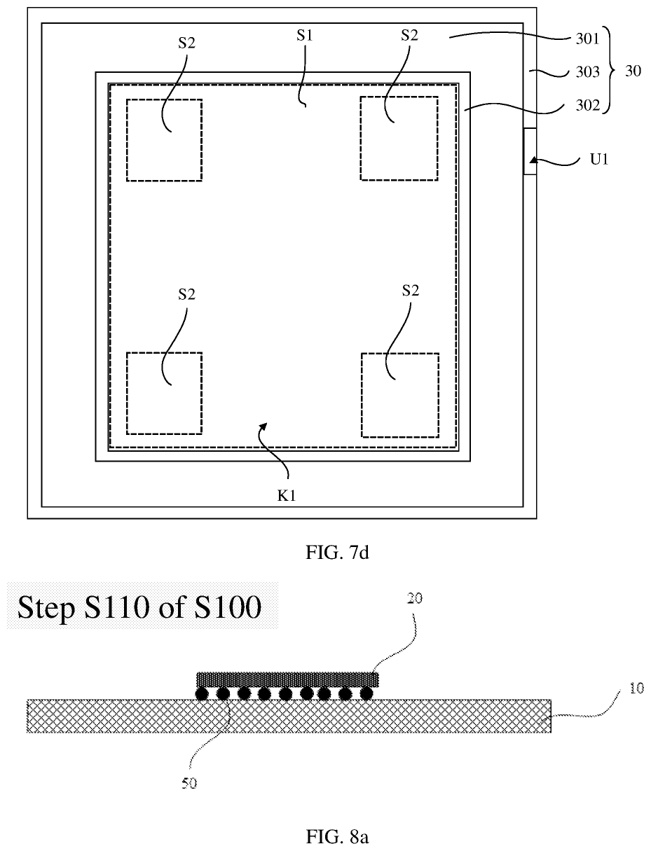

FIG. 7a is a schematic diagram of another packaging structure according to an embodiment of this disclosure. FIG. 7b is a bottom view (a view in a direction P1) of a heat spreader 30 in FIG. 7a. As shown in FIG. 7a and FIG. 7b, a difference from the packaging structure shown in FIG. 3a to FIG. 4b lies in that the heat spreader 30 includes one thermally conductive cover 301, one support component 303, and a plurality of enclosure ribs 302 (only four enclosure ribs are shown in the figure as an example), there are a plurality of filling areas S1 on a surface that is of the thermally conductive cover 301 and that faces the substrate 10, each enclosure rib 302 is disposed along a corresponding filling area S1, and each enclosure rib 302 and a filling area S1 enclosed by the enclosure rib 302 form one accommodation cavity K1. For descriptions of each part of each accommodation cavity K1, refer to disposing of the accommodation cavity K1 in the embodiments corresponding to FIG. 3a to FIG. 4b. A plurality of chips 20 in a one-to-one correspondence with a plurality of accommodation cavitys K1 are disposed on the substrate 10; in other words, each chip 20 cooperates with one accommodation cavity K1, and each accommodation cavity K1 corresponds to one chip 20. The thermal interface material layer 40 is filled between each chip 20 and a chip heat-conducting area S2 on a bottom surface of a corresponding accommodation cavity K1, and each accommodation cavity K1 is filled with the filling material 70. For disposing and possible variations of each group of chip 20, thermal interface material layer 40, filling material 70, and accommodation cavity K1, refer to corresponding disposing and related variations of a group of chip 20, thermal interface material layer 40, filling material 70, and accommodation cavity K1 in the embodiments corresponding to FIG. 3a to FIG. 4b. For example, a manner of forming each accommodation cavity K1 may alternatively be a manner of forming the accommodation cavity K1 in FIG. 5a and FIG. 5b. Each accommodation cavity K1 has an adjacent dent U1 on the support component 303. Therefore, each heat spreader 30 may simultaneously maintain valid thermal contact with a plurality of chips 20.

Each accommodation cavity K1 may alternatively cooperate with more than one chip 20. FIG. 7c is a schematic diagram of another packaging structure according to an embodiment of this disclosure. FIG. 7d is a bottom view of a heat spreader in FIG. 7c. With reference to FIG. 7c and FIG. 7d, a difference from the embodiments corresponding to FIG. 3a to FIG. 4b lies in that a plurality of chip heat-conducting areas S2 (there are four chip heat-conducting areas in the figure as an example) are distributed at intervals in a range of each filling area S1. Each chip heat-conducting area S2 cooperates with one chip 20, the thermal interface material layer 40 is filled between each chip 20 and a corresponding chip heat-conducting area S2, and the accommodation cavity K1 is filled with the filling material 70. A filling depth of the filling material 70 may be adjusted according to a requirement. For details, refer to descriptions of the filling material 70 in the foregoing embodiments. A part of or the entire side surface c of each chip 20 may be covered, or only a side surface of each thermal interface material layer 40 may be covered.

In addition, a plurality of accommodation cavities may alternatively be disposed on a surface that is of a thermally conductive cover of the heat spreader and that faces the substrate, and each accommodation cavity includes one or more chips 20.

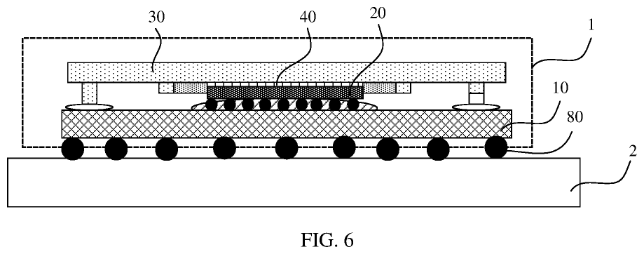

Based on example inventive concept, an embodiment of this disclosure provides an electronic device. The electronic device may be a server, a computer, a tablet computer, a mobile phone, or the like. The electronic device includes a circuit board 2 and the packaging structure provided in the foregoing embodiments. A substrate in the packaging structure is fastened on a surface of the circuit board in a manner such as an FCBGA or an FCLGA, and is electrically connected to a pad on the surface of the circuit board. FIG. 6 is a schematic diagram of cooperation between a packaging structure 1 and the circuit board 2 in the electronic device according to this embodiment of this disclosure. For details, refer to FIG. 6. A substrate 10 of the packaging structure 1 is fastened to and electrically connected to the circuit board 2 in an FCBGA manner. More specifically, a pin of the substrate 10 is electrically connected to a pad on the substrate 10 by using a solder ball 80. As shown in FIG. 3a, the filling material 70 in the accommodation cavity K1 encircles a side surface of the thermal interface material layer 40, to prevent external air from causing damage such as oxidation or vulcanization to the thermal interface material layer 40, and ensure good thermal contact between the chip 20 and the thermally conductive cover 301. This is conducive to full heat dissipation of the chip 20. For a variation and an effect of the packaging structure 1, refer to the packaging structure provided in the foregoing embodiments.

Based on an example inventive concept, an embodiment of this disclosure further provides a chip packaging method used to form the packaging structure provided in the foregoing embodiments.

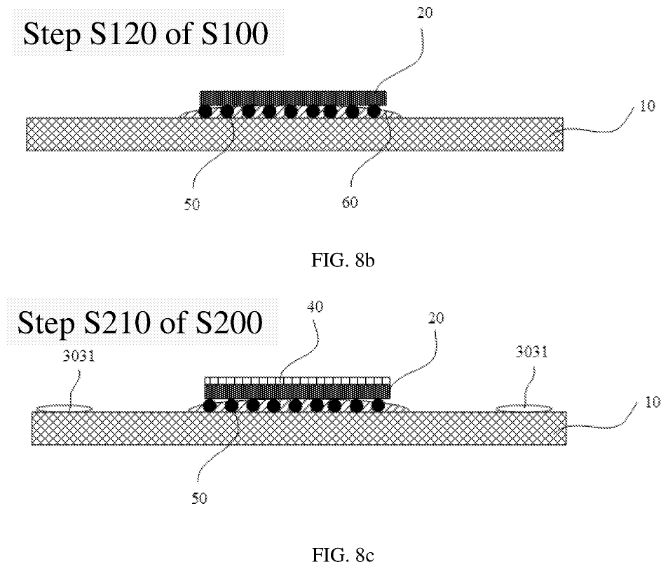

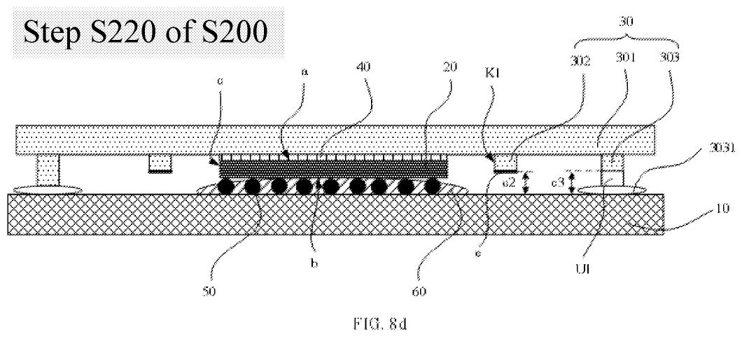

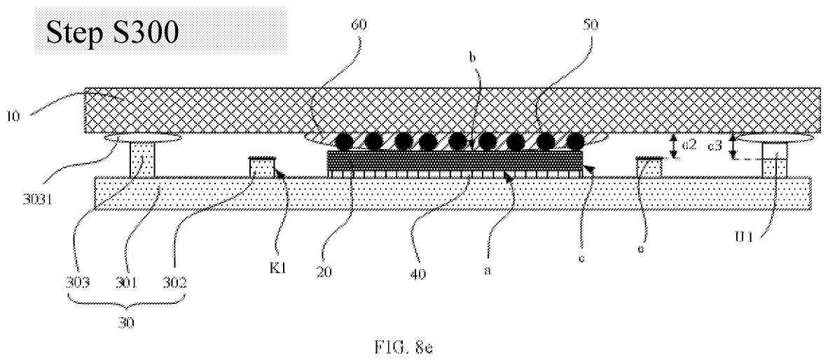

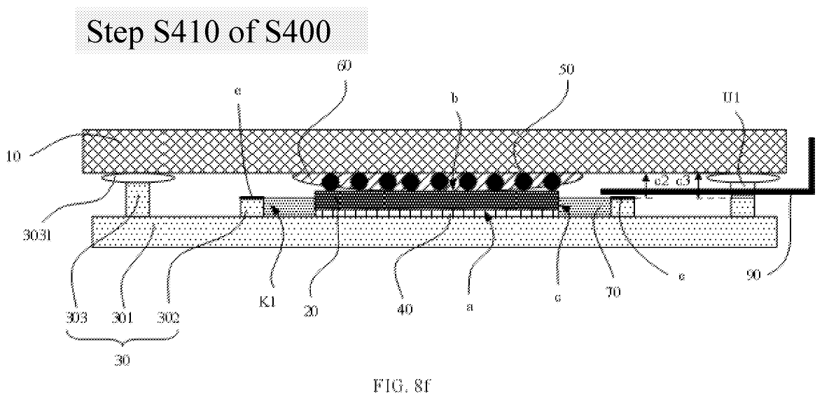

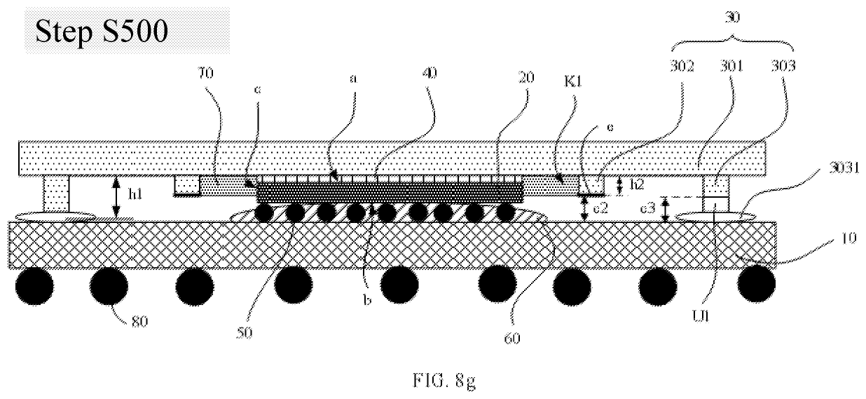

For example, a material of the thermal interface material layer is indium, and a material of the filling material is liquid silica gel or polyolefin resin. FIG. 8a to FIG. 8g are schematic diagrams obtained after steps in the chip packaging method are performed.

The method includes:

S100: Mount a chip 20 on a surface of a substrate.

Specifically, step S110 is performed first. As shown in FIG. 8a, solder balls 50 are deposited on a pad on a bottom surface b of a chip 20, and the solder balls 50 are correspondingly connected to the pad on the substrate 10 through reflow soldering.

Then, step S120 is performed. As shown in FIG. 8b, an underfill 60 is poured into a gap between the solder balls 50. Specifically, epoxy resin is applied to an edge of the chip 20 by using a capillary action, and the epoxy resin saturates between a bottom surface b of the chip 20 and the substrate 10, and is filled between the solder balls 50.

S200: Mount a thermally conductive cover on a side that is of the chip 20 and that is away from the substrate.

Specifically, step S210 is performed first. As shown in FIG. 8c, a indium sheet 40 is placed on a top surface a of the chip 20, and an adhesive 3031 is applied at a location that is on a surface of the substrate 10 and that corresponds to a support component 303 of a heat spreader 30.

Then, step S220 is performed. As shown in FIG. 8d, the heat spreader 30 is mounted. For a structure of the heat spreader 30, refer to the structure of the heat spreader 30 in FIG. 3a and FIG. 3b. An opening of the heat spreader 30 faces the substrate 10, a chip heat-conducting area S2 is pressed against the indium sheet 40, the support component 303 is pressed against the adhesive 3031, and apart of the chip 20 is disposed in an accommodation cavity K1. A first gap c2 is formed between the substrate 10 and a surface e (that is, an opening edge of the accommodation cavity K1) that is of an enclosure rib 302 and that faces the substrate 10, and a dent U1 cooperates with the substrate 10 to form a second gap c3. Then, the indium sheet 40 and the adhesive 3031 are cured at high temperature. A process of performing curing at high temperature may be as follows: Temperature is first increased to proper temperature, and the adhesive is cured first. In this case, the temperature may be, for example, approximately 125° C. Then, the temperature is increased to 160° C. to 170° C., so that the indium sheet melts. Then, the temperature is decreased to approximately 150° C., so that the molten indium is cured to form the thermal interface material layer 40.

S300: Flip the substrate, so that an opening of the accommodation cavity faces upward.

Specifically, as shown in FIG. 8e, the substrate 10, the heat spreader 30, and the chip 20 are flipped by 180° as a whole, so that the opening of the accommodation cavity K1 faces upward. In this way, when a filling material 70 is poured into the accommodation cavity K1 in a next step, the filling material 70 can be limited in the accommodation cavity K1.

S400: Pour the filling material into the accommodation cavity through the second gap, and cure the filling material.

Specifically, step S410 is performed. As shown in FIG. 8f, a pipe 90 passes through the second gap c3 and extends above the opening of the accommodation cavity K1, and the pipe 90 pours a liquid filling material 70 into the accommodation cavity K1.

Then, step 410 is performed, and the filling material 70 is cured and molded to form the packaging structure shown in FIG. 3a.

S500: Perform balling on a surface that is of the substrate and that is away from the chip 20.

Specifically, as shown in FIG. 8g, a plurality of solder balls 80 are placed on a pad on a surface that is of the substrate 10 and that is away from the chip 20.

It should be noted that, in the foregoing step S220, when the heat spreader 30 is mounted, the support component 303 in the heat spreader 30 and the thermally conductive cover 301 are in an integrated structure; or although the support component 303 and the thermally conductive cover 301 are in a separated structure, the support component 303 and the thermally conductive cover 301 are bonded and fastened in advance. The “integrated structure” is an integrally formed structure, and the “separated structure” is a structure in which different structures that are separately formed first are spliced in a manner such as soldering or bonding. However, this is merely an example. When the support component 303 and the thermally conductive cover 301 are in a separated structure, the support component 303 may be an independent annular structure. In this case, the foregoing step S220 may be decomposed into at least the following two steps.

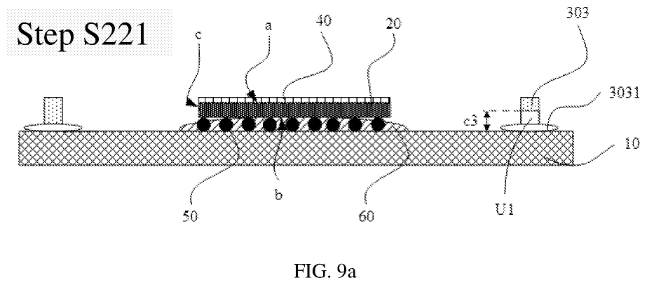

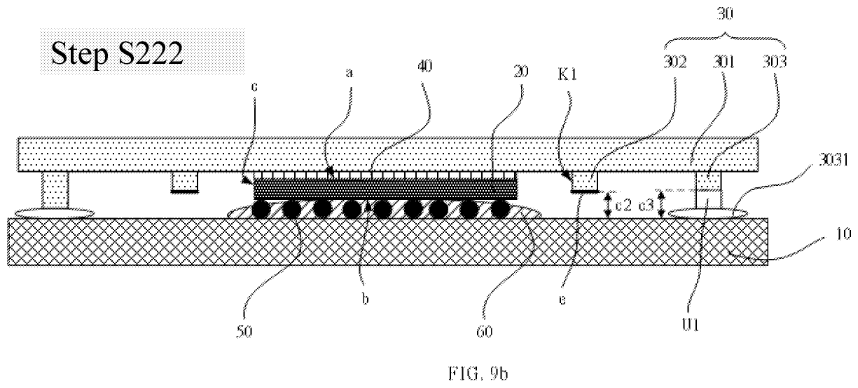

S221: As shown in FIG. 9a, first press the support component 303 against the adhesive 3031, to first fasten the support component 303 to the substrate 10, where the dent U1 cooperates with the substrate 10 to form the second gap c3, and the support component 303 is disposed around the chip 20.

S222: As shown in FIG. 9b, place the thermally conductive cover 301 with the accommodation cavity K1 on the side that is of the chip 20 and that is away from the substrate 10, and fixedly connect, by using an adhesive or the like, the thermally conductive cover 301 to an end that is of the support component 303 and that is away from the substrate 10. For a cooperation manner between the chip 20 and the accommodation cavity K1 and a cooperation manner between the thermal interface material layer 40 and the accommodation cavity K1, and a cooperation manner between the first gap c2 and the second gap c3, refer to related descriptions in the foregoing step S200.

In addition, the enclosure rib 302 and the thermally conductive cover 303 may be in an integrated structure, or may be in a separated structure, and before step S222 is performed, the enclosure rib 302 is fastened to a surface of the thermally conductive cover 303. The support component 303 with the dent U1 in step S221 may be directly molded; or before step S221, the dent U1 may be formed in a manner such as etching or cutting on a surface that is of the annular support component 303 and that is used for connecting the substrate 10.

The heat spreader 30 may have the accommodation cavity K1 when being purchased, or step S150 may be further included between step S100 and step S200: Dispose the enclosure rib 302 along an edge of a filling area S1 of the thermally conductive cover 301. For example, the enclosure rib 302 may be fastened to the surface of the thermally conductive cover 301 through bonding or soldering, and the enclosure rib 302 and the filling area S1 enclosed by the enclosure rib 302 form one accommodation cavity K1.

Alternatively, when the accommodation cavity K1 is recessed on the thermally conductive cover 301, as shown in FIG. 5a, step S150 is correspondingly changed to: Form, at a corresponding location in the filling area S1, a groove that is recessed on the substrate 01 in a manner such as etching, cutting, or stamping, where the groove forms one accommodation cavity K1.

Step S150 may alternatively be another manner that can be used to form the accommodation cavity K1.

In addition, the dent U1 on the support component 303 may be processed when being obtained, or the dent U1 may be formed before step S200 in a manner such as cutting or etching.

In addition, when the packaging structure shown in FIG. 4a needs to be formed, step S200 may alternatively be replaced with the following manner

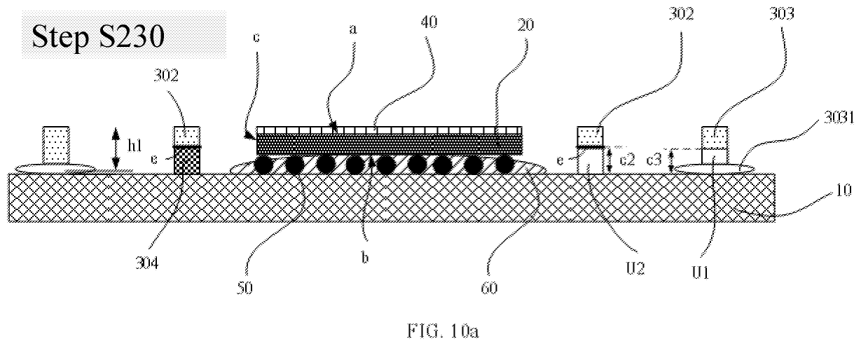

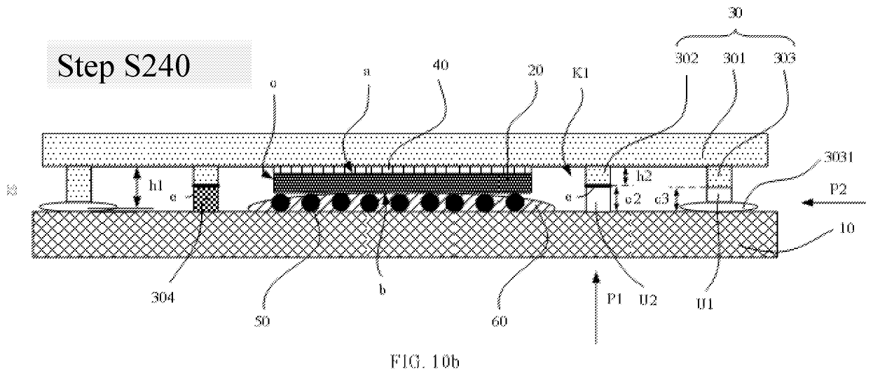

First, step S230 is performed, as shown in FIG. 10a. An extension rib 304 is fastened to the substrate 10 in a manner of bonding or the like, the extension rib 304 surrounds the chip 20, and the enclosure rib 302 is disposed at an end that is of the extension rib 304 and that is away from the substrate 10. The enclosure rib 302 and the extension rib 304 may be in an integrated structure, or may be in a spliced separated structure. The extension rib 304 has a hollow U2, and the hollow U2 extends from an end that is of the extension rib 304 and that is away from the enclosure rib 302 to the enclosure rib 302. After the extension rib 304 is fastened to the substrate 10, the extension rib 304 may be considered as a ring with a notch (the hollow U2), and the hollow U2 cooperates with the substrate 10 to form the first gap c2. Correspondingly, the support component 303 is also fastened to the substrate 10. The support component 303 is disposed around the enclosure rib 302, the dent U1 on the support component 303 cooperates with the substrate 10 to form the second gap c3, and the second gap c3 corresponds to the first gap c2.

Then, step S240 is performed, as shown in FIG. 10b. The thermally conductive cover 301 is placed on a side that is of the chip 20 and that is away from the substrate 10, an edge of the filling area S1 of the thermally conductive cover 301 is connected to the enclosure rib 302 in a manner of bonding or the like, and the enclosure rib 302 and the filling area S1 form one accommodation cavity K1. Correspondingly, the support component 303 is fastened to the thermally conductive cover 301 in a manner of bonding or the like.

It should be noted that, in step S230, the support component 303 may alternatively not be fastened to the substrate 10 first, but is fastened to the thermally conductive cover 301 first, and then, in step S240, the support component S303 is fastened to the substrate 10.

For other beneficial effects of the method, refer to descriptions of related effects in the embodiments of the foregoing packaging structure.

It should be noted that the foregoing method is merely an example. For a possible variation (including but not limited to a material, a connection manner, and a structure form) of each part of the packaging structure, refer to the descriptions of the packaging structure in the foregoing embodiments, and the chip packaging method is appropriately adjusted.

For example, when the thermally conductive cover is configured to dissipate heat for a plurality of chips 20, refer to the form of the packaging structure in FIG. 7a to FIG. 7d. In step S200, each accommodation cavity needs to cooperate with only one chip 20.

For another example, when each thermally conductive cover has a plurality of accommodation cavitys, refer the form of the packaging structure corresponding to FIG. 7a and FIG. 7b. In step S400, the filling material 70 may be poured into a corresponding accommodation cavity K1 through each second gap c3, or the filling material 70 may be poured into a plurality of accommodation cavitys K1 through only one second gap c3.

When one accommodation cavity includes a plurality of chips 20, refer to the form of the packaging structure corresponding to FIG. 7c and FIG. 7d. In step S400, the filling material 70 is poured into only one accommodation cavity K1, so that the filling material 70 can separately cover side surfaces c of different chips 20 in the accommodation cavity K1 and a corresponding thermal interface material layer 40.

The foregoing descriptions are merely specific implementations of this disclosure, but are not intended to limit the protection scope of this disclosure. Any variation or replacement readily figured out by a person skilled in the art within the technical scope disclosed in this disclosure shall fall within the protection scope of this disclosure. Therefore, the protection scope of this disclosure shall be subject to the protection scope of the claims.

What is claimed is:

1. A packaging structure comprising:
a substrate, a thermally conductive cover, and at least one chip; wherein:
the thermally conductive cover is disposed on a side that is of the at least one chip and that is away from the substrate;
at least one filling area is on a surface that is of the thermally conductive cover and that faces the substrate;
each of the at least one filling area corresponds to the at least one chip;
at least one accommodation cavity whose opening faces the substrate is in each of the at least one filling area;
a thermal interface material layer is filled between each of the at least one chip and a bottom surface of a corresponding one of the at least one accommodation cavity;
each of the at least one accommodation cavity is filled with a filling material;
the filling material encircles a side surface of the thermal interface material layer in each of the at least one accommodation cavity; and
a first gap is connected to the at least one accommodation cavity and is defined between at least a partial opening edge of each accommodation cavity and the substrate.

2. The packaging structure of claim 1, further comprising at least one enclosure rib, wherein the at least one enclosure rib is connected to the thermally conductive cover and is disposed along an edge of each of the at least one filling area, and each of the at least one enclosure rib and a corresponding one of the at least one filling area form one of the at least one accommodation cavity.

3. The packaging structure of claim 2, wherein the first gap is formed between each of the at least one enclosure rib and the substrate.

4. The packaging structure of claim 3, wherein a width of the first gap is between 30 μm and 2 mm

5. The packaging structure of claim 2, further comprising at least one extension rib, wherein the at least one extension rib is connected between the substrate and an end that is of each of the at least one enclosure rib and that is away from the thermally conductive cover, the at least one extension rib has a hollow extending from the at least one enclosure rib to the substrate, and the hollow forms the first gap.

6. The packaging structure of claim 2, wherein each of the at least one enclosure rib and the thermally conductive cover are in a separated structure.

7. The packaging structure of claim 2, wherein each of the at least one enclosure rib and the thermally conductive cover are in an integrated structure.

8. The packaging structure of claim 1, wherein each of the at least one filling area is recessed in a direction away from the substrate to form one of the at least one accommodation cavity.

9. The packaging structure of claim 1, further comprising a support component, wherein the support component is disposed between the substrate and the thermally conductive cover and is separately connected to the substrate and the thermally conductive cover; and
the support component surrounds the at least one accommodation cavity corresponding to the at least one chip, and a second gap corresponding to the first gap is formed between a part of the support component and the substrate.

10. The packaging structure of claim 9, wherein the support component and the thermally conductive cover are in a separated structure.

11. The packaging structure of claim 1, wherein a melting point of the filling material in each of the at least one accommodation cavity, is higher than a melting point of the thermal interface material layer.

12. The packaging structure of claim 11, wherein the filling material in each of the at least one accommodation cavity covers at least a part of a side surface of each of the at least one chip.

13. The packaging structure of claim 11, wherein
a material of the thermal interface material layer in each of the at least one accommodation cavity is indium, indium/silver, tin/silver/copper, or indium/tin/bismuth; and
a material of the filling material is one or a combination of more of silica gel, polyolefin resin, epoxy resin, modified epoxy resin, silicone resin, and modified silicone resin.

14. An electronic device comprising a circuit board and the packaging structure, the packaging structure comprising:
a substrate, a thermally conductive cover, and at least one chip, wherein:
the thermally conductive cover is disposed on a side that is of the at least one chip and that is away from the substrate;
at least one filling area is on a surface that is of the thermally conductive cover and that faces the substrate;
each of the at least one filling area corresponds to the at least one chip;
at least one accommodation cavity whose opening faces the substrate is in each of the at least one filling area;
a thermal interface material layer is filled between each of the at least one chip and a bottom surface of a corresponding one of the at least one accommodation cavity;
each of the at least one accommodation cavity is filled with a filling material;
the filling material encircles a side surface of the thermal interface material layer in each of the at least one accommodation cavity;
a first gap is connected to the at least one accommodation cavity and is defined between at least a partial opening edge of each of the at least one accommodation cavity and the substrate; and
the substrate is mounted on the circuit board and is electrically connected to the circuit board.

15. The electronic device of claim 14, further comprising at least one enclosure rib, wherein the at least one enclosure rib is connected to the thermally conductive cover and is disposed along an edge of each of the at least one filling area, and each of the at least one enclosure rib and a corresponding one of the at least one filling area form one of the at least one accommodation cavity.

16. A chip packaging method comprising:
mounting at least one chip on a surface of a substrate;
mounting a thermally conductive cover on a side that is of the at least one chip and that is away from the substrate, wherein:
at least one filling area is on a surface that is of the thermally conductive cover and that faces the substrate;
each of the at least one filling area corresponds to the at least one chip;
at least one accommodation cavity whose opening faces the substrate is in each of the at least one filling area;
a thermal interface material layer is filled between each of the at least one chip and a bottom surface of a corresponding one of the at least one accommodation cavity; and
a first gap is connected to the at least one accommodation cavity and is defined between at least a partial opening edge of each of the at least one accommodation cavity and the substrate; and
pouring a filling material into each of the at least one accommodation cavity through the first gap corresponding to the at least one accommodation cavity, and curing the filling material;
wherein the filling material encircles at least a side surface of the thermal interface material layer in each of the at least one accommodation cavity.

17. The method of claim 16, further comprising, before the mounting the thermally conductive cover on the side that is of the at least one chip and that is away from the substrate:
forming the at least one accommodation cavity in each of the at least one filling area of the thermally conductive cover.

18. The method of claim 17, wherein the forming of the at least one accommodation cavity in each of the at least one filling area of the thermally conductive cover comprises:
forming at least one enclosure rib along an edge of each of the at least one filling area of the thermally conductive cover, wherein each of the at least one enclosure rib and a corresponding one of the at least one filling area form one of the at least one accommodation cavity.

19. The method of claim 17, wherein the forming of the at least one accommodation cavity in each of the at least one filling area of the thermally conductive cover comprises:
forming, in each of the at least one filling area of the thermally conductive cover, at least one groove that is recessed toward an inner side of the thermally conductive cover, wherein each of the at least one groove forms one of the at least one accommodation cavity.

20. The method of claim 16, wherein the mounting of the thermally conductive cover on the side that is of the at least one chip and that is away from the substrate comprises:
fastening at least one extension rib to the substrate, wherein each of the at least one extension rib surrounds the at least one chip, at least one enclosure rib is disposed along an end that is of each of the at least one extension rib and that is away from the substrate, each of the at least one extension rib has a hollow, and the hollow extends from the substrate to a corresponding one of the at least one enclosure rib, to form the first gap; and
placing the thermally conductive cover on the side that is of the at least one chip and that is away from the substrate, and enabling an end that is of each of the at least one enclosure rib and that is away from a corresponding one of the at least one extension rib to be connected to the thermally conductive cover, wherein each of the at least one enclosure rib extends along an edge of a corresponding one of the at least one filling area, and each of the at least one enclosure rib and the corresponding one of the at least one filling area form one of the at least one accommodation cavity.
